(19) United States
(12) Patent Application Publication
(10) Pub. No.: US 2025/0211175 A1
(43) Pub. Date: Jun. 26, 2025

(54) Doherty Power Amplifier

(71) Applicant: South China University of Technology, Guangzhou, Guangdong (CN)

(72) Inventors: Quan XUE, Guangzhou, Guangdong (CN); Jiawen CHEN, Guangzhou, Guangdong (CN); Haoshen ZHU, Guangzhou, Guangdong (CN)

(73) Assignee: South China University of Technology, Guangzhou, Guangdong (CN)

(21) Appl. No.: 18/851,307

(22) PCT Filed: Dec. 12, 2022
(86) PCT No.: PCT/CN2022/138414

§ 371 Date: Sep. 26, 2024

(30) Foreign Application Priority Data
Apr. 2, 2022 (CN) 202210355365.0

(51) Int. Cl. H03F 1/02; H03F 1/56; H03F 3/24; H03F 3/45; H03F 3/60

(52) U.S. Cl. CPC H03F 1/0288; H03F 1/565; H03F 3/245; H03F 3/45183; H03F 3/604; H03F 2200/192

(57) ABSTRACT

The present disclosure discloses a Doherty power amplifier, including: a quadrature coupler including a first coupled inductor and a second coupled inductor, the quadrature coupler being configured to split an input signal into a first signal and a second signal; a first amplifier circuit, configured to amplify the first signal; a second amplifier circuit, configured to amplify the second signal; and a load modulation network, which is an output voltage-combined Doherty load modulation network using a T equivalent model. An overlapping part of the coupled inductors is used to provide distributed parasitic capacitance, thereby eliminating the need to set an additional capacitor in the quadrature coupler, and therefore reducing an area. Through the T equivalent model, a quarter-wavelength transmission line is equated to the load modulation network of the embodiments of the present disclosure, multiple inductors are combined into transformers with small areas.

### CROSS-REFERENCE TO RELATED APPLICATIONS

This application is a national stage filing under 35 U.S.C. § 371 of international application number PCT/CN2022/138414, filed Dec. 22, 2022, which claims priority to Chinese patent application No. 202210355365.0 filed on Apr. 2, 2022. The contents of these applications are incorporated herein by reference in their entirety.

### TECHNICAL FIELD

The present disclosure relates to the field of electronic communication technologies, in particular, to a Doherty power amplifier.

### BACKGROUND

In recent years, the development of 5th generation (5G) mobile communication technology has imposed higher requirements for the bandwidth and speed of data transmission, with a radio frequency (RF) front-end transceiver system being a current hot research topic in 5G communication. In the RF front-end transceiver system, the main characteristic of a power amplifier is to amplify an RF signal to a certain power level and minimize direct current (DC) power consumption. Therefore, the performance of the power amplifier determines the main performance of a transmit (TX) channel of a transceiver. In an RF system, the power amplifier is located at the end of a transmitter, and an output power of the power amplifier determines a propagation distance of a signal in the air. In addition, in order to reduce the power consumption of the whole transmitter and prolong a service life, the efficiency of the power amplifier is also one of the most important design indicators. Affected by a peak-to-average power ratio (PAPR) of a quadrature amplitude modulation (QAM)-modulated signal used in 5G communication, the power amplifier may operate in a power back-off state. Therefore, the operating efficiency of the power amplifier can be maximized by improving the back-off efficiency of the power amplifier. In an existing technology, a Doherty structure is a relatively mature technique to improve the back-off efficiency of power amplifiers. However, the conventional Doherty structure has the disadvantages of narrow bandwidth and large area.

In order to overcome the disadvantages of narrow bandwidth and large area of the conventional Doherty structure, in recent years researchers have mainly optimized the Doherty structure in the following two manners. In a first manner, a compact voltage-combined transformer-based matching network design is proposed, in which a quarter-wavelength transmission line is equated to a pi-network, and resonant inductance and an ideal transformer are introduced to form an on-chip transformer model, so as to obtain a voltage-combined transformer-based load modulation network, thereby reducing an area occupied by the load modulation network in the Doherty structure. However, the pi-type equivalent network will introduce resonance at high frequency in a power back-off state, which limits the high-frequency working performance of the power amplifier and reduces the broadband performance of the power amplifier. In a second manner, a Doherty power amplifier structure using dual-adaptive biases is proposed, in which auxiliary power amplifiers are completely turned off in a low power working state to improve the back-off efficiency, and an adaptive power divider is introduced to distribute, in the low power working state, more power to main power amplifiers, thus reducing an intrinsic loss caused by power distribution. However, because a transmission line is used for matching in a load modulation network of the Doherty power amplifier structure using dual-adaptive biases, a load modulation effect is poor, and thus the back-off efficiency has not been significantly improved.

### SUMMARY

To solve the above technical problem, an embodiment of the present disclosure provides a Doherty power amplifier.

A technical scheme used in the embodiment of the present disclosure is:
a Doherty power amplifier, including:
a quadrature coupler including a first coupled inductor and a second coupled inductor, the quadrature coupler being configured to split an input signal into a first signal and a second signal with a 90° phase difference;
a first amplifier circuit, configured to amplify the first signal;
a second amplifier circuit, configured to amplify the second signal; and
a load modulation network including a third coupled inductor, a fourth coupled inductor, a first inductor, a first capacitor, and a second capacitor, where two ends of a primary coil of the third coupled inductor are connected to an output port of the first amplifier circuit, a first end of a secondary coil of the third coupled inductor is connected to a first end of the first inductor, a second end of the first inductor is grounded, the second end of the first inductor is connected to a second end of the first capacitor, a first end of the first capacitor is connected to the first end of the first inductor, the first end of the first inductor is further used to connect to a signal output, a second end of the secondary coil of the third coupled inductor is connected to a first end of a secondary coil of the fourth coupled inductor, the first end of the secondary coil of the fourth coupled inductor is connected to a first end of the second capacitor, a second end of the second capacitor is connected to a second end of the secondary coil of the fourth coupled inductor, the second end of the secondary coil of the fourth coupled inductor is grounded, two ends of a primary coil of the fourth coupled inductor are connected to an output port of the second amplifier circuit, and a center tap of each of the primary coil of the third coupled inductor and the primary coil of the fourth coupled inductor is connected to a power supply.

As an optional implementation, the quadrature coupler further includes a first resistor, a first end of a primary coil of the first coupled inductor is used to connect to a signal input, a second end of the primary coil of the first coupled inductor is connected to a first end of a primary coil of the second coupled inductor, a first end of a secondary coil of the second coupled inductor is connected to a second end of a secondary coil of the first coupled inductor, a second end of the secondary coil of the second coupled inductor is connected to a first end of the first resistor, and a second end of the first resistor is grounded.

As an optional implementation, the first amplifier circuit includes a first matching network, a second matching network, a first differential amplifier, and a second differential amplifier, where
a first output port of the second differential amplifier is connected to a first end of the primary coil of the third coupled inductor, and a second output port of the second differential amplifier is connected to a second end of the primary coil of the third coupled inductor.

As an optional implementation, the first matching network includes a fifth coupled inductor, and the second matching network includes a sixth coupled inductor;
a first end of a primary coil of the fifth coupled inductor is connected to a first end of the secondary coil of the first coupled inductor, a second end of the primary coil of the fifth coupled inductor is grounded, a first end of a secondary coil of the fifth coupled inductor is connected to a first input port of the first differential amplifier, a second end of the secondary coil of the fifth coupled inductor is connected to a second input port of the first differential amplifier, and a center tap of the secondary coil of the fifth coupled inductor is grounded; and
a first end of a primary coil of the sixth coupled inductor is connected to a first output port of the first differential amplifier, a second end of the primary coil of the sixth coupled inductor is connected to a second output port of the first differential amplifier, a center tap of the primary coil of the sixth coupled inductor is connected to the power supply, a first end of a secondary coil of the sixth coupled inductor is connected to a first input port of the second differential amplifier, and a second end of the secondary coil of the sixth coupled inductor is connected to a second input port of the second differential amplifier.

As an optional implementation, the second amplifier circuit includes a third matching network, a fourth matching network, a third differential amplifier, and a fourth differential amplifier; and
a first output port of the fourth differential amplifier is connected to a first end of the primary coil of the fourth coupled inductor, and a second output port of the fourth differential amplifier is connected to a second end of the primary coil of the fourth coupled inductor.

As an optional implementation, the third matching network includes a seventh coupled inductor, and the fourth matching network includes an eighth coupled inductor;
a first end of a primary coil of the seventh coupled inductor is connected to a second end of the primary coil of the second coupled inductor, a second end of the primary coil of the seventh coupled inductor is grounded, a first end of a secondary coil of the seventh coupled inductor is connected to a first input port of the third differential amplifier, a second end of the secondary coil of the seventh coupled inductor is connected to a second input port of the third differential amplifier, and a center tap of the secondary coil of the seventh coupled inductor is grounded; and
a first end of a primary coil of the eighth coupled inductor is connected to a first output port of the fourth differential amplifier, a second end of the primary coil of the eighth coupled inductor is connected to a second output port of the fourth differential amplifier, a center tap of the primary coil of the eighth coupled inductor is connected to the power supply, a first end of a secondary coil of the eighth coupled inductor is connected to a first input port of the fourth differential amplifier, and a second end of the secondary coil of the eighth coupled inductor is connected to a second input port of the fourth differential amplifier.

As an optional implementation, the first differential amplifier includes a second resistor, a third resistor, a third capacitor, a fourth capacitor, a first MOS transistor, and a second MOS transistor, where
a second end of the third resistor is connected to the second input port of the first differential amplifier, a first end of the third resistor is connected to a second end of the second resistor, the second end of the second resistor is connected to a first bias voltage, a first end of the second resistor is connected to each of the first input port of the first differential amplifier and a gate of the first MOS transistor, the gate of the first MOS transistor is connected to a first end of the third capacitor, a second end of the third capacitor is connected to a drain of the second MOS transistor, the drain of the second MOS transistor is connected to the second output port of the first differential amplifier, a gate of the second MOS transistor is connected to a second end of the third resistor, a source of the second MOS transistor is connected to a source of the first MOS transistor, the source of the first MOS transistor is grounded, a drain of the first MOS transistor is connected to the first output port of the first differential amplifier, the drain of the first MOS transistor is connected to a first end of the fourth capacitor, and a second end of the fourth capacitor is connected to the gate of the second MOS transistor.

As an optional implementation, the first differential amplifier, the second differential amplifier, the third differential amplifier, and the fourth differential amplifier use differential amplifiers of same structure.

As an optional implementation, the Doherty power amplifier further includes an adaptive bias circuit, where the adaptive bias circuit performs conversion according to an envelope amplitude of the second signal to obtain a DC voltage signal, and controls working states of the third differential amplifier and the fourth differential amplifier according to the DC voltage signal.

As an optional implementation, the adaptive bias circuit includes a fifth capacitor, a sixth capacitor, a seventh capacitor, an eighth capacitor, a fourth resistor, a fifth resistor, a sixth resistor, a seventh resistor, a third MOS transistor, a fourth MOS transistor, and a fifth MOS transistor, where
a first end of the fifth capacitor is connected to a second end of the primary coil of the second coupled inductor, a second end of the fifth capacitor is connected to a first end of the fourth resistor, a second end of the fourth resistor is connected to a second bias voltage, the first end of the fourth resistor is connected to a gate of the third MOS transistor, a source of the third MOS transistor is grounded, a drain of the third MOS transistor is connected to a second end of the sixth capacitor, a first end of the sixth capacitor is connected to a first end of the fifth resistor, the first end of the fifth resistor is connected to the power supply, a second end of the fifth resistor is connected to the drain of the third MOS transistor, the drain of the third MOS transistor is connected to a gate of the fourth MOS transistor, a source of the fourth MOS transistor is grounded, a drain of the fourth MOS transistor is connected to a second end of the sixth resistor, a first end of the sixth resistor is used to output the DC voltage signal as a bias voltage to the third differential amplifier, the second end of the sixth resistor is connected to a first end of the seventh capacitor, a second end of the seventh capacitor is grounded, the gate of the fourth MOS transistor is connected to a gate of the fifth MOS transistor, a source of the fifth MOS transistor is grounded, a drain of the fifth MOS transistor is connected to a second end of the seventh resistor, a first end of the seventh resistor is used to output the DC voltage signal as a bias voltage to the fourth differential amplifier, the second end of the seventh resistor is connected to a first end of the eighth capacitor, and a second end of the eighth capacitor is grounded.

In the Doherty power amplifier according to the embodiment of the present disclosure, an overlapping part of the first coupled inductor and the second coupled inductor is used to provide distributed parasitic capacitance. This improves a phase balance of the quadrature coupler, eliminates the need to set an additional capacitor in the quadrature coupler, reduces a connection trace of the capacitor, and thus reduces an area of a Doherty structure. Through a T equivalent model, a quarter-wavelength transmission line is equated to a load modulation network of the embodiments of the present disclosure, multiple inductors are combined into transformers with small areas, and a voltage-combined load modulation network is realized in a compact structure. This further reduces the area of the Doherty structure while improving the back-off efficiency of the power amplifier, reduces a connection loss, and improves the overall performance of the power amplifier.

### BRIEF DESCRIPTION OF DRAWINGS

FIG. 1 is a circuit diagram of a Doherty power amplifier according to an embodiment of the present disclosure;

FIG. 2 is a design diagram of a load modulation network of a Doherty power amplifier according to an embodiment of the present disclosure;

FIG. 3 is a curve graph of an impedance change of a load modulation network of a Doherty power amplifier according to an embodiment of the present disclosure;

FIG. 4 shows a quadrature coupler equivalent model of a Doherty power amplifier according to an embodiment of the present disclosure;

FIG. 5 is a curve graph of amplitude and phase characteristics of a quadrature coupler of a Doherty power amplifier according to an embodiment of the present disclosure;

FIG. 6 is a principle diagram of a differential amplifier of a Doherty power amplifier according to an embodiment of the present disclosure;

FIG. 7 is a principle diagram of an adaptive configuration circuit of a Doherty power amplifier according to an embodiment of the present disclosure; and

FIG. 8 is a curve graph of performance of a Doherty power amplifier according to an embodiment of the present disclosure.

List of reference numerals: 101: Quadrature coupler; 102: First amplifier circuit; 103: Second amplifier circuit; 104: Load modulation network; TF₁: First coupled inductor; TF₂: Second coupled inductor; TF₃: Third coupled inductor; TF₄: Fourth coupled inductor; TF₅: Fifth coupled inductor; TF₆: Sixth coupled inductor; TF₇: Seventh coupled inductor; TF₈: Eighth coupled inductor; R₁: First resistor; L₁: First inductor; C₁: First capacitor; C₂: Second capacitor; RFᵢₙ: Signal input; RFₒᵤₜ: Signal output; U₁: First differential amplifier; U₂: Second differential amplifier; U₃: Third differential amplifier; U₄: Fourth differential amplifier; VDD: Power supply; R₂: Second resistor; R₃: Third resistor; M₁: First MOS transistor; M₂: Second MOS transistor; C₃: Third capacitor; C₄: Fourth capacitor; C₅: Fifth capacitor; C₆: Sixth capacitor; C₇: Seventh capacitor; C₈: Eighth capacitor; R₄: Fourth resistor; R₅: Fifth resistor; R₆: Sixth resistor; R₇: Seventh resistor; M₃: Third MOS transistor; M₄: Fourth MOS transistor; M₅: Fifth MOS transistor; V_{bias1}: First bias voltage; V_{bias2}: Second bias voltage; and ABC: Adaptive bias circuit.

### DETAILED DESCRIPTION

In order to enable those having ordinary skill in the art to better understand technical schemes of the present disclosure, the technical schemes in the embodiments of the present disclosure are clearly and completely described in the following with reference to the drawings in the embodiments of the present disclosure. It is obvious that the described embodiments are only some embodiments of the present disclosure and are not exhaustive. All other embodiments obtained by those having ordinary skill in the art based on the embodiments of the present disclosure without inventive effort shall fall within the scope of protection of the present disclosure.

The terms “first”, “second”, “third”, “fourth”, etc. in the description, the claims and the drawings of the present disclosure are intended to distinguish between different objects and are not necessarily to describe a specific order. Further, the terms “include” and “have” and any variations thereof are intended to encompass non-exclusive inclusion. For example, a process, method, system, product, or device that includes a series of steps or components is not limited to those steps or components listed, but may also optionally include additional steps or components that are not explicitly stated or are inherent to such a process, method, product, or device.

The term “embodiment” mentioned in the article means that a particular feature, structure, or characteristic described in connection with the embodiment may be included in at least one embodiment of the present disclosure. Appearance of the term in various parts in the specification does not necessarily refer to the same embodiment, nor is it an independent or alternative embodiment mutually exclusive of other embodiments. It is understood explicitly and implicitly by those skilled in the art that the embodiments described herein may be combined with other embodiments.

In recent years, the development of 5G mobile communication technology has imposed higher requirements for the bandwidth and speed of data transmission, with an RF front-end transceiver system being a current hot research topic in 5G communication. In the RF front-end transceiver system, the main characteristic of a power amplifier is to amplify an RF signal to a certain power level and minimize DC power consumption. Therefore, the performance of the power amplifier determines the main performance of a TX channel of a transceiver. In an RF system, the power amplifier is located at the end of a transmitter, and an output power of the power amplifier determines a propagation distance of a signal in the air. In addition, in order to reduce the power consumption of the whole transmitter and prolong a service life, the efficiency of the power amplifier is also one of the most important design indicators. Affected by a PAPR of a QAM modulated signal used in 5G communication, the power amplifier may operate in a power back-off state. Therefore, the operating efficiency of the power amplifier can be maximized by improving the back-off efficiency of the power amplifier. In an existing technology, a Doherty structure is a relatively mature technique to improve the back-off efficiency of power amplifiers. However, the conventional Doherty structure has the disadvantages of narrow bandwidth and large area.

In order to overcome the disadvantages of narrow bandwidth and large area of the conventional Doherty structure, in recent years, researchers have mainly optimized the Doherty structure in the following two manners. In a first manner, a compact voltage-combined transformer-based matching network design is proposed, in which a quarter-wavelength transmission line is equated to a pi-network, and resonant inductance and an ideal transformer are introduced to form an on-chip transformer model, so as to obtain a voltage-combined transformer-based load modulation network, thereby reducing an area occupied by the load modulation network in the Doherty structure. However, the pi-type equivalent network will introduce resonance at high frequency in a power back-off state, which limits the high-frequency working performance of the power amplifier and reduces the broadband performance of the power amplifier. In a second manner, a Doherty power amplifier structure using dual-adaptive biases is proposed, in which auxiliary power amplifiers are completely turned off in a low power working state to improve the back-off efficiency, and an adaptive power divider is introduced to distribute, in the low power working state, more power to main power amplifiers, thus reducing an intrinsic loss caused by power distribution. However, a transmission line is used for matching in a load modulation network of the Doherty power amplifier structure using dual-adaptive biases, therefore a load modulation effect is poor and the back-off efficiency has not been significantly improved.

In view of this, the embodiments of the present disclosure propose a Doherty power amplifier, in which an overlapping part of a first coupled inductor and a second coupled inductor is used to provide distributed parasitic capacitance. This improves a phase balance of a quadrature coupler, eliminates the need to set an additional capacitor in the quadrature coupler, reduces a connection trace of the capacitor, and thus reduces an area of a Doherty structure. Through a T equivalent model, a quarter-wavelength transmission line is equated to a load modulation network of the embodiments of the present disclosure, multiple inductors are combined into transformers with small areas, and a voltage-combined load modulation network is realized in a compact structure. This further reduces the area of the Doherty structure while improving the back-off efficiency of the power amplifier, reduces a connection loss, and improves the overall performance of the power amplifier.

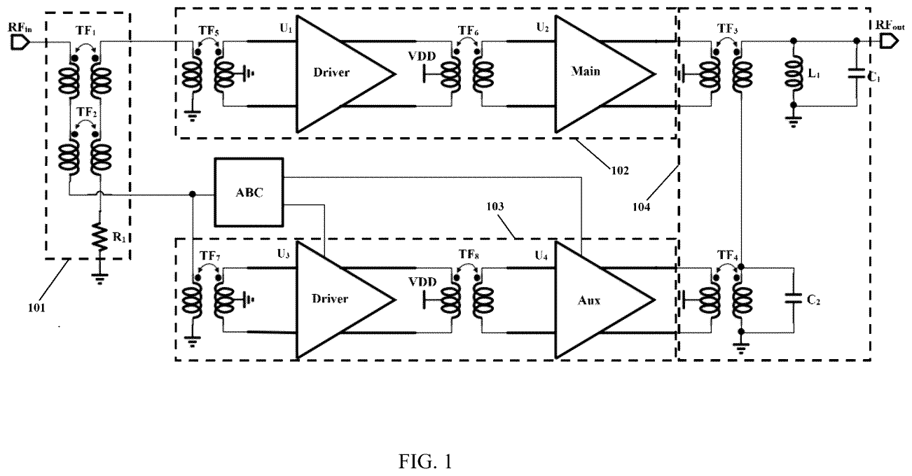

As shown in FIG. 1, an embodiment of the present disclosure proposes a Doherty power amplifier, including:
a quadrature coupler 101 including a first coupled inductor TF₁ and a second coupled inductor TF₂, the quadrature coupler being configured to split an input signal into a first signal and a second signal with a 90° phase difference;
a first amplifier circuit 102, configured to amplify the first signal;
a second amplifier circuit 103, configured to amplify the second signal;
a load modulation network 104 including a third coupled inductor TF₃, a fourth coupled inductor TF₄, a first inductor L₁, a first capacitor C₁, and a second capacitor C₂, where two ends of a primary coil of the third coupled inductor TF₃ are connected to an output port of the first amplifier circuit 102, a first end of a secondary coil of the third coupled inductor TF₃ is connected to a first end of the first inductor L1, a second end of the first inductor L₁ is grounded, the second end of the first inductor L₁ is connected to a second end of the first capacitor C₁, a first end of the first capacitor C₁ is connected to the first end of the first inductor L₁, the first end of the first inductor L₁ is further used to connect to a signal output RFᵢₙ, a second end of the secondary coil of the third coupled inductor TF₃ is connected to a first end of a secondary coil of the fourth coupled inductor TF₄, the first end of the secondary coil of the fourth coupled inductor TF₄ is connected to a first end of the second capacitor C₂, a second end of the second capacitor C₂ is connected to a second end of the secondary coil of the fourth coupled inductor TF₄, the second end of the secondary coil of the fourth coupled inductor TF₄ is grounded, two ends of a primary coil of the fourth coupled inductor TF₄ are connected to an output port of the second amplifier circuit 103, and a center tap of each of the primary coil of the third coupled inductor TF₃ and the primary coil of the fourth coupled inductor TF₄ is connected to a power supply VDD.

Here, in the quadrature coupler 101 in the embodiment of the present disclosure, an overlapping part of the first coupled inductor TF₁ and the second coupled inductor TF₂ to provide distributed parasitic capacitance. This improves a phase balance of the quadrature coupler 101, eliminates the need to set an additional capacitor in the quadrature coupler 101, reduces a connection trace of the capacitor, and thus reduces an area of a Doherty structure.

The load modulation network 104 of the embodiment of the present disclosure is an output voltage-combined Doherty load modulation network, and an amplifier in the first amplifier circuit 102 has high load impedance in a low power state, and the load impedance decreases in a high power state, with an output power increasing accordingly. The voltage-combined Doherty load modulation network does not affect the broadband characteristic of the power amplifier, but effectively realizes a load modulation effect, and improves the back-off efficiency of the Doherty power amplifier of the embodiment of the present disclosure.

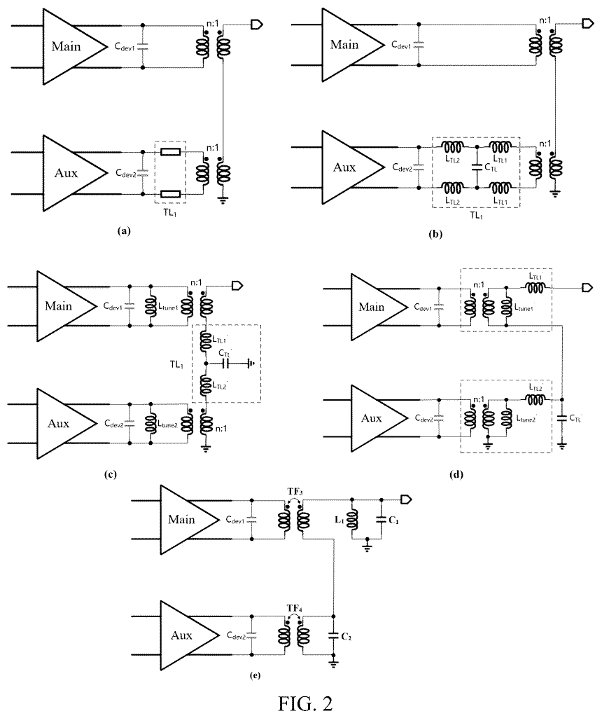

Specifically, referring to FIG. 2, a design principle of the load modulation network 104 of the embodiment of the present disclosure is shown in FIGS. 2(a)-(e). FIG. 2(a) shows a conventional voltage-combined load modulation network, which consists of two ideal n:1 transformers and a quarter-wavelength transmission line TL₁. C_{dev1} and C_{dev2} are output parasitic capacitors of amplifiers. First, the quarter-wavelength transmission line is equated to a T equivalent model consisting of L_{TL1}, L_{TL2} and C_{TL}, as shown in FIG. 2(b); then, according to properties of the ideal n:1 transformers, the T equivalent model is moved to the other ends of the transformers, and L_{TL1} and L_{TL2} become L_{TL1}′ and L_{TL2}′, and at the same time, inductors Lₜᵤₙₑ₁ and Lₜᵤₙₑ₂ are connected in parallel at output ends of the amplifiers for resonance with C_{dev1} and C_{dev2}, as shown in FIG. 2(c); next, L_{TL1}′ is moved upward and Lₜᵤₙₑ₁ and Lₜᵤₙₑ₂ are moved to the other ends of the transformers respectively to become Lₜᵤₙₑ₁′ and Lₜᵤₙₑ₂′, and in this case, ITF₁, Lₜᵤₙₑ₁′, and L_{TL1}′ and ITF₂, Lₜᵤₙₑ₂′, and L_{TL2}′ respectively form two on-chip transformer equivalent models, as shown in FIG. 2(d); and finally, a first inductor L1 is disposed at the output end to resonate with an output capacitor, that is, the first capacitor C₁, to obtain the load modulation network according to the embodiment of the present disclosure, as shown in FIG. 2(e).

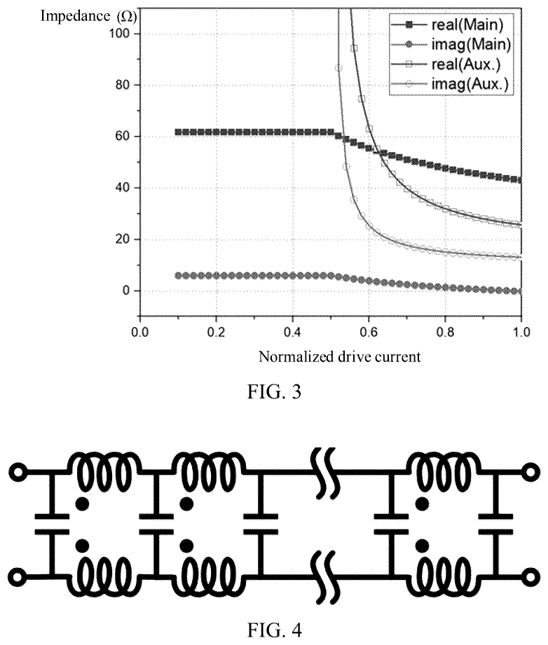

FIG. 3 shows changes of load impedance of the load modulation network 104 according to an embodiment of the present disclosure. Load impedance of a Main amplifier (that is, a second differential amplifier U₂) exhibits higher impedance at a low power, which ensures high efficiency of the power amplifier. At a high power, an Aux amplifier (that is, a fourth differential amplifier U₄) gradually outputs current. In this case, the load impedance of the Main amplifier gradually decreases, and an output power can be further increased.

In the present disclosure, through a T equivalent model, a quarter-wavelength transmission line is equated to the load modulation network 104 of the embodiment of the present disclosure, multiple inductors are combined into transformers with small areas, and a voltage-combined load modulation network is realized in a compact structure. This further reduces the area of the Doherty structure while improving the back-off efficiency of the power amplifier, reduces a connection loss, and improves the overall performance of the power amplifier.

As an optional implementation, the quadrature coupler 101 further includes a first resistor R₁. A first end of a primary coil of the first coupled inductor TF₁ is used to connect to a signal input RFᵢₙ, a second end of the primary coil of the first coupled inductor TF₁ is connected to a first end of a primary coil of the second coupled inductor TF₂, a first end of a secondary coil of the second coupled inductor TF₂ is connected to a second end of a secondary coil of the first coupled inductor TF₁, a second end of the secondary coil of the second coupled inductor TF₂ is connected to a first end of the first resistor R₁, and a second end of the first resistor R₁ is grounded.

Here, the first resistor R₁ is an isolation resistor.

An equivalent model of the quadrature coupler 101 of the embodiment of the present disclosure is shown in FIG. 4. A coil overlapping part of the first coupled inductor TF₁ and the second coupled inductor TF₂ provides capacitance required in quadrature coupling. This eliminates the need to set an additional capacitor in the quadrature coupler 101, reduces a connection trace of the capacitor, and thus reduces the area of the Doherty structure.

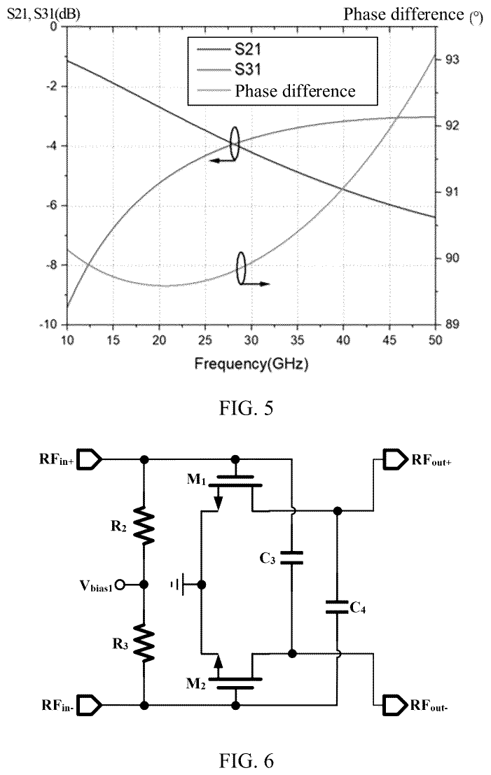

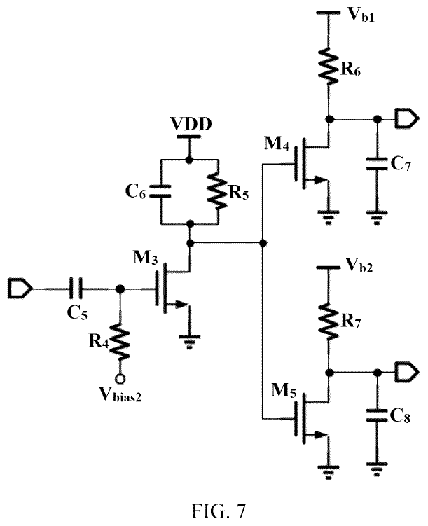

FIG. 5 shows the amplitude and phase characteristics of the quadrature coupler 101 according to an embodiment of the present disclosure. Refer to FIG. 5. A phase difference between the first signal and the second signal is about 90°, indicating that the quadrature coupler 101 of the embodiment of the present disclosure realizes a quadrature power distribution effect.

As an optional implementation, the first amplifier circuit 102 includes a first matching network, a second matching network, a first differential amplifier U₁, and a second differential amplifier U₂.

A first output of the second differential amplifier U₂ is connected to a first end of the primary coil of the third coupled inductor TF₃, and a second output of the second differential amplifier U₂is connected to a second end of the primary coil of the third coupled inductor TF₃. Here, the first matching network is an input matching network for providing impedance matching for an input of the first differential amplifier U₁; and a second matching network is an inter-stage matching network for providing impedance matching to an input of the second differential amplifier U₂. Input impedance matching of the amplifier is performed through the first matching network and the second matching network to maximize a gain and power transfer of the first amplifier circuit 102.

As an optional implementation, the first matching network includes a fifth coupled inductor TF₅, and the second matching network includes a sixth coupled inductor TF₆.

A first end of a primary coil of the fifth coupled inductor TF₅ is connected to a first end of the secondary coil of the first coupled inductor TF₁, a second end of the primary coil of the fifth coupled inductor TF₅ is grounded, a first end of a secondary coil of the fifth coupled inductor TF₅ is connected to a first input port of the first differential amplifier U₁, a second end of the secondary coil of the fifth coupled inductor TF₅ is connected to a second input port of the first differential amplifier U₁, and a center tap of the secondary coil of the fifth coupled inductor TF₅ is grounded.

A first end of a primary coil of the sixth coupled inductor TF₆ is connected to a first output port of the first differential amplifier U₁, a second end of the primary coil of the sixth coupled inductor TF₆ is connected to a second output port of the first differential amplifier U₁, a center tap of the primary coil of the sixth coupled inductor TF₆ is connected to the power supply VDD, a first end of a secondary coil of the sixth coupled inductor TF₆ is connected to a first input of the second differential amplifier U₂, and a second end of the secondary coil of the sixth coupled inductor TF₆ is connected to a second input port of the second differential amplifier U₂.

As an optional implementation, the second amplifier circuit 103 includes a third matching network, a fourth matching network, a third differential amplifier U₃, and a fourth differential amplifier U₄.

A first output port of the fourth differential amplifier U₄ is connected to a first end of the primary coil of the fourth coupled inductor TF₄, and a second output port of the fourth differential amplifier U₄ is connected to a second end of the primary coil of the fourth coupled inductor TF₄.

Here, a third matching network is an input matching network for providing impedance matching for an input of the third differential amplifier U₃; and a fourth matching network is an inter-stage matching network for providing impedance matching to an input of the fourth differential amplifier U₄. Input impedance matching of the amplifier is performed through the third matching network and the fourth matching network to maximize a gain and power transfer of the second amplifier circuit 103.

As an optional implementation, the third matching network includes a seventh coupled inductor TF₇, and the fourth matching network includes an eighth coupled inductor.

A first end of a primary coil of the seventh coupled inductor TF₇ is connected to a second end of the primary coil of the second coupled inductor TF₂, a second end of the primary coil of the seventh coupled inductor TF₇ is grounded, a first end of a secondary coil of the seventh coupled inductor TF₇ is connected to a first input port of the third differential amplifier U₃, a second end of the secondary coil of the seventh coupled inductor TF₇ is connected to a second input port of the third differential amplifier U₃, and a center tap of the secondary coil of the seventh coupled inductor TF₇ is grounded.

A first end of a primary coil of the eighth coupled inductor TF₈ is connected to a first output port of the fourth differential amplifier U₄, a second end of the primary coil of the eighth coupled inductor TF₈ is connected to a second output port of the fourth differential amplifier U₄, a center tap of the primary coil of the eighth coupled inductor TF₈ is connected to the power supply VDD, a first end of a secondary coil of the eighth coupled inductor TF₈ is connected to a first input port of the fourth differential amplifier U₄, and a second end of the secondary coil of the eighth coupled inductor TF₈ is connected to a second input port of the fourth differential amplifier U₄.

Refer to FIG. 6. As an optional implementation, the first differential amplifier U₁ includes a second resistor R₂, a third resistor R₃, a third capacitor C₃, a fourth capacitor C₄, a first MOS transistor M₁, and a second MOS transistor M₂.

A second end of the third resistor R₃ is connected to the second input port of the first differential amplifier U₁, a first end of the third resistor R₃ is connected to a second end of the second resistor R₂, the second end of the second resistor R₂ is connected to a first bias voltage V_{bias1}, a first end of the second resistor R₂ is connected to each of the first input port of the first differential amplifier U₁ and a gate of the first MOS transistor M₁, the gate of the first MOS transistor M₁ is connected to a first end of the third capacitor C₃, a second end of the third capacitor C₃ is connected to a drain of the second MOS transistor M₂, the drain of the second MOS transistor M₂ is connected to the second output port of the first differential amplifier U₁, a gate of the second MOS transistor M₂ is connected to a second end of the third resistor R₃, a source of the second MOS transistor M₂ is connected to a source of the first MOS transistor M₁, the source of the first MOS transistor M₁ is grounded, a drain of the first MOS transistor M₁ is connected to the first output port of the first differential amplifier U₁, the drain of the first MOS transistor M₁ is connected to a first end of the fourth capacitor C₄, and a second end of the fourth capacitor C₄ is connected to the gate of the second MOS transistor M₂.

Here, the first MOS transistor M₁ and the second MOS transistor M₂ form a differential pair of the first differential amplifier U₁.

The third capacitor C₃ and the fourth capacitor C₄ are neutralizing capacitors for suppressing harmful parasitic oscillations.

The second resistor R₂ and the third resistor R₃ are bias resistors for adjusting gate bias currents of the first MOS transistor M₁ and the second MOS transistor M₂.

As an optional implementation, the first differential amplifier U₁, the second differential amplifier U₂, the third differential amplifier U₃, and the fourth differential amplifier U₄ use differential amplifiers of same structure, that is, the differential amplifier structure shown in FIG. 6.

As an optional implementation, an adaptive bias circuit ABC is further included, where the adaptive bias circuit ABC performs conversion according to an envelope amplitude of the second signal to obtain a DC voltage signal, and controls working states of the third differential amplifier U₃ and the fourth differential amplifier U₄ according to the DC voltage signal.

Specifically, detection of the envelope amplitude of the second signal and conversion of an amplitude of an RF AC signal into the DC voltage signal are performed to control bias voltages of the third differential amplifier U₃ and the fourth differential amplifier U₄, so that the third differential amplifier U₃ and the fourth differential amplifier U₄ are completely turned off in a low power state. This reduces the consumption of DC power, and further improves the back-off efficiency of the Doherty power amplifier of the embodiment of the present disclosure.

As an optional implementation, the adaptive bias circuit includes a fifth capacitor C₅, a sixth capacitor C₆, a seventh capacitor C₇, an eighth capacitor C₈, a fourth resistor R₄, a fifth resistor R₅, a sixth resistor R₆, a seventh resistor R₇, a third MOS transistor M₃, a fourth MOS transistor M₄, and a fifth MOS transistor M₅.

A first end of the fifth capacitor C₅ is connected to a second end of the primary coil of the second coupled inductor TF₂, a second end of the fifth capacitor C₅ is connected to a first end of the fourth resistor R₄, a second end of the fourth resistor R₄ is connected to a second bias voltage V_{bias2}, the first end of the fourth resistor R₄ is connected to a gate of the third MOS transistor M₃, a source of the third MOS transistor M₃ is grounded, a drain of the third MOS transistor M₃ is connected to a second end of the sixth capacitor C₆, a first end of the sixth capacitor C₆ is connected to a first end of the fifth resistor R₅, the first end of the fifth resistor R₅ is connected to the power supply VDD, a second end of the fifth resistor R₅ is connected to the drain of the third MOS transistor M₃, the drain of the third MOS transistor M₃ is connected to a gate of the fourth MOS transistor M₄, a source of the fourth MOS transistor M₄ is grounded, a drain of the fourth MOS transistor M₄ is connected to a second end of the sixth resistor R₆, a first end of the sixth resistor R₆ is used to output the DC voltage signal as a bias voltage to the third differential amplifier U₃, the second end of the sixth resistor R₆ is connected to a first end of the seventh capacitor C₇, a second end of the seventh capacitor C₇ is grounded, the gate of the fourth MOS transistor M₄ is connected to a gate of the fifth MOS transistor M₅, a source of the fifth MOS transistor M₅ is grounded, a drain of the fifth MOS transistor M₅ is connected to a second end of the seventh resistor R₇, a first end of the seventh resistor R₇ is used to output the DC voltage signal as a bias voltage to the fourth differential amplifier U₄, the second end of the seventh resistor R₇ is connected to a first end of the eighth capacitor C₈, and a second end of the eighth capacitor C₈ is grounded.

Here, the fifth capacitor C₅ is an input DC blocking capacitor for isolating an input DC voltage,
the fourth resistor R₄ is a bias resistor for adjusting a gate bias current of the third MOS transistor M₃,
the fifth resistor R₅, the sixth resistor R₆, and the seventh resistor R₇ are load resistors, and
the sixth capacitor C₆, the seventh capacitor C₇, and the eighth capacitor C₈ are decoupling capacitors for removing interference of a high-frequency signal.

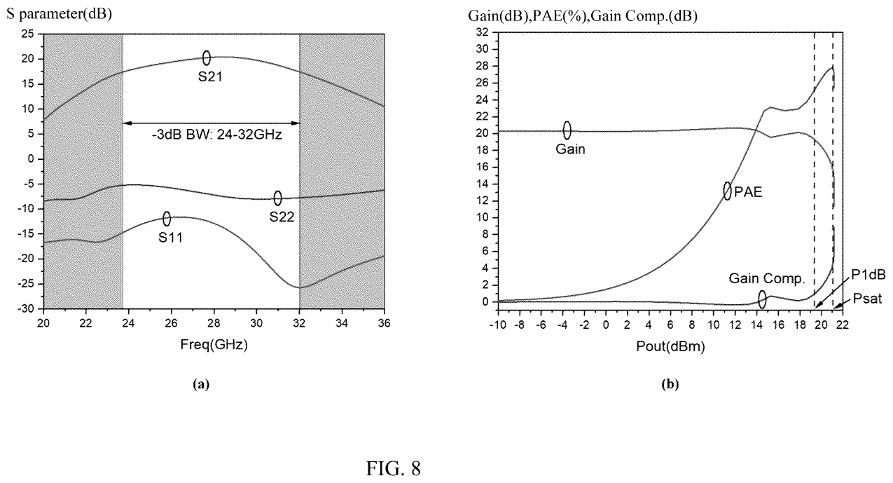

FIG. 8 shows the performance of a Doherty power amplifier according to an embodiment of the present disclosure. Specifically, FIG. 8(a) illustrates small signal S parameters of a Doherty power amplifier according to an embodiment of the present disclosure: A 3 dB bandwidth is 24-32 GHz, a small signal gain S21 is 20 dB, and S11 is always less than −10 dB in the frequency band. FIG. 8(b) illustrates the large-signal linearity and efficiency performance of a Doherty power amplifier at 27 GHz according to an embodiment of the present disclosure, with a saturated output power of 21 dBm, a peak PAE of 27%, and 6 dB back-off efficiency of 23%.

In summary; in the Doherty power amplifier according to the embodiments of the present disclosure, an overlapping part of the first coupled inductor and the second coupled inductor is used to provide distributed parasitic capacitance. This improves a phase balance of the quadrature coupler, eliminates the need to set an additional capacitor in the quadrature coupler, reduces a connection trace of the capacitor, and thus reduces the area of the Doherty structure. Through the T equivalent model, a quarter-wavelength transmission line is equated to the load modulation network of the embodiments of the present disclosure, multiple inductors are combined into transformers with small areas, and the voltage-combined load modulation network is realized in a compact structure. This further reduces the area of the Doherty structure while improving the back-off efficiency of the power amplifier, reduces a connection loss, and improves the overall performance of the power amplifier.

The above is a detailed description of the preferred implementation of the present disclosure, but the present disclosure is not limited to the above-mentioned embodiments. Those of ordinary skill in the art can also make various equivalent modifications or replacements without departing from the spirit of the present disclosure, and these equivalent modifications or replacements are all included in the scope defined by the claims of the present disclosure.

What is claimed is:

1. A Doherty power amplifier, comprising:
a quadrature coupler comprising a first coupled inductor and a second coupled inductor, the quadrature coupler being configured to split an input signal into a first signal and a second signal with a 90° phase difference;
a first amplifier circuit, configured to amplify the first signal;
a second amplifier circuit, configured to amplify the second signal; and
a load modulation network comprising a third coupled inductor, a fourth coupled inductor, a first inductor, a first capacitor, and a second capacitor, wherein two ends of a primary coil of the third coupled inductor are connected to an output port of the first amplifier circuit, a first end of a secondary coil of the third coupled inductor is connected to a first end of the first inductor, a second end of the first inductor is grounded, the second end of the first inductor is connected to a second end of the first capacitor, a first end of the first capacitor is connected to the first end of the first inductor, the first end of the first inductor is further used to connect to a signal output, a second end of the secondary coil of the third coupled inductor is connected to a first end of a secondary coil of the fourth coupled inductor, the first end of the secondary coil of the fourth coupled inductor is connected to a first end of the second capacitor, a second end of the second capacitor is connected to a second end of the secondary coil of the fourth coupled inductor, the second end of the secondary coil of the fourth coupled inductor is grounded, two ends of a primary coil of the fourth coupled inductor are connected to an output port of the second amplifier circuit, and a center tap of each of the primary coil of the third coupled inductor and the primary coil of the fourth coupled inductor is connected to a power supply; wherein
the quadrature coupler further comprises a first resistor, a first end of a primary coil of the first coupled inductor is used to connect to a signal input, a second end of the primary coil of the first coupled inductor is connected to a first end of a primary coil of the second coupled inductor, a first end of a secondary coil of the second coupled inductor is connected to a second end of a secondary coil of the first coupled inductor, a second end of the secondary coil of the second coupled inductor is connected to a first end of the first resistor, and a second end of the first resistor is grounded;
the first amplifier circuit comprises a first matching network, a second matching network, a first differential amplifier, and a second differential amplifier;
a first output port of the second differential amplifier is connected to a first end of the primary coil of the third coupled inductor, and a second output port of the second differential amplifier is connected to a second end of the primary coil of the third coupled inductor;
the first matching network comprises a fifth coupled inductor, and the second matching network comprises a sixth coupled inductor;
a first end of a primary coil of the fifth coupled inductor is connected to a first end of the secondary coil of the first coupled inductor, a second end of the primary coil of the fifth coupled inductor is grounded, a first end of a secondary coil of the fifth coupled inductor is connected to a first input port of the first differential amplifier, a second end of the secondary coil of the fifth coupled inductor is connected to a second input port of the first differential amplifier, and a center tap of the secondary coil of the fifth coupled inductor is grounded; and
a first end of a primary coil of the sixth coupled inductor is connected to a first output port of the first differential amplifier, a second end of the primary coil of the sixth coupled inductor is connected to a second output port of the first differential amplifier, a center tap of the primary coil of the sixth coupled inductor is connected to the power supply, a first end of a secondary coil of the sixth coupled inductor is connected to a first input port of the second differential amplifier, and a second end of the secondary coil of the sixth coupled inductor is connected to a second input port of the second differential amplifier.

2. The Doherty power amplifier according to claim 1, wherein the second amplifier circuit comprises a third matching network, a fourth matching network, a third differential amplifier, and a fourth differential amplifier; and
a first output port of the fourth differential amplifier is connected to a first end of the primary coil of the fourth coupled inductor, and a second output port of the fourth differential amplifier is connected to a second end of the primary coil of the fourth coupled inductor.

3. The Doherty power amplifier according to claim 2, wherein the third matching network comprises a seventh coupled inductor, and the fourth matching network comprises an eighth coupled inductor;
a first end of a primary coil of the seventh coupled inductor is connected to a second end of the primary coil of the second coupled inductor, a second end of the primary coil of the seventh coupled inductor is grounded, a first end of a secondary coil of the seventh coupled inductor is connected to a first input port of the third differential amplifier, a second end of the secondary coil of the seventh coupled inductor is connected to a second input port of the third differential amplifier, and a center tap of the secondary coil of the seventh coupled inductor is grounded; and
a first end of a primary coil of the eighth coupled inductor is connected to a first output port of the fourth differential amplifier, a second end of the primary coil of the eighth coupled inductor is connected to a second output port of the fourth differential amplifier, a center tap of the primary coil of the eighth coupled inductor is connected to the power supply, a first end of a secondary coil of the eighth coupled inductor is connected to a first input port of the fourth differential amplifier, and a second end of the secondary coil of the eighth coupled inductor is connected to a second input port of the fourth differential amplifier.

4. The Doherty power amplifier according to claim 2, wherein the first differential amplifier comprises a second resistor, a third resistor, a third capacitor, a fourth capacitor, a first MOS transistor, and a second MOS transistor, wherein
a second end of the third resistor is connected to the second input port of the first differential amplifier, a first end of the third resistor is connected to a second end of the second resistor, the second end of the second resistor is connected to a first bias voltage, a first end of the second resistor is connected to each of the first input port of the first differential amplifier and a gate of the first MOS transistor, the gate of the first MOS transistor is connected to a first end of the third capacitor, a second end of the third capacitor is connected to a drain of the second MOS transistor, the drain of the second MOS transistor is connected to the second output port of the first differential amplifier, a gate of the second MOS transistor is connected to a second end of the third resistor, a source of the second MOS transistor is connected to a source of the first MOS transistor, the source of the first MOS transistor is grounded, a drain of the first MOS transistor is connected to the first output port of the first differential amplifier, the drain of the first MOS transistor is connected to a first end of the fourth capacitor, and a second end of the fourth capacitor is connected to the gate of the second MOS transistor.

5. The Doherty power amplifier according to claim 4, wherein the first differential amplifier, the second differential amplifier, the third differential amplifier, and the fourth differential amplifier use differential amplifiers of same structure.

6. The Doherty power amplifier according to claim 2, further comprising an adaptive bias circuit, wherein the adaptive bias circuit performs conversion according to an envelope amplitude of the second signal to obtain a direct current (DC) voltage signal, and controls working states of the third differential amplifier and the fourth differential amplifier according to the DC voltage signal.

7. The Doherty power amplifier according to claim 6, wherein the adaptive bias circuit comprises a fifth capacitor, a sixth capacitor, a seventh capacitor, an eighth capacitor, a fourth resistor, a fifth resistor, a sixth resistor, a seventh resistor, a third MOS transistor, a fourth MOS transistor, and a fifth MOS transistor; and
wherein a first end of the fifth capacitor is connected to a second end of the primary coil of the second coupled inductor, a second end of the fifth capacitor is connected to a first end of the fourth resistor, a second end of the fourth resistor is connected to a second bias voltage, the first end of the fourth resistor is connected to a gate of the third MOS transistor, a source of the third MOS transistor is grounded, a drain of the third MOS transistor is connected to a second end of the sixth capacitor, a first end of the sixth capacitor is connected to a first end of the fifth resistor, the first end of the fifth resistor is connected to the power supply, a second end of the fifth resistor is connected to the drain of the third MOS transistor, the drain of the third MOS transistor is connected to a gate of the fourth MOS transistor, a source of the fourth MOS transistor is grounded, a drain of the fourth MOS transistor is connected to a second end of the sixth resistor, a first end of the sixth resistor is used to output the DC voltage signal as a bias voltage to the third differential amplifier, the second end of the sixth resistor is connected to a first end of the seventh capacitor, a second end of the seventh capacitor is grounded, the gate of the fourth MOS transistor is connected to a gate of the fifth MOS transistor, a source of the fifth MOS transistor is grounded, a drain of the fifth MOS transistor is connected to a second end of the seventh resistor, a first end of the seventh resistor is used to output the DC voltage signal as a bias voltage to the fourth differential amplifier, the second end of the seventh resistor is connected to a first end of the eighth capacitor, and a second end of the eighth capacitor is grounded.
